(19) United States
(12) Patent Application Publication
(10) Pub. No.: US 2002/0109194 A1
(43) Pub. Date: Aug. 15, 2002

(54) Semiconductor device

(76) Inventor: Kazuteru Ishizuka, Kanagawa (JP)

Correspondence Address: Darryl G. Walker, WALKER & SAKO, LLP, Suite 235, 300 South First Street, San Jose, CA, 95113, US

(21) Appl. No.: 10/027,297

(22) Filed: Dec. 21, 2001

(30) Foreign Application Priority Data
Dec. 27, 2000 (JP) 2000-397173

(51) Int. Cl. H01L 31/062

(52) U.S. Cl. 257/368

(57) ABSTRACT

A semiconductor device including an element isolation area having a shallow trench isolation (STI) structure has been disclosed. The semiconductor device may include transistors (Q1 to Q4). Transistors (Q1 to Q4) may include gates (FG1 to FG4) that may be square, rectangular or circular loops in their plan views. Gates (FG1 to FG4) may be formed to cover edge portions on the sides of diffusion layers (L1 and L2) at the interface with a field region (STI structure). In this way, divots (DIV) may not cause adverse affects on desired operating characteristics.

### TECHNICAL FIELD

The present invention relates generally to a semiconductor device and more particularly to a semiconductor device having an element isolation that includes a shallow trench isolation structure.

### BACKGROUND OF THE INVENTION

Due to the need of semiconductor memories having large storage capacity, devices are becoming finer and more compact. As devices have become finer and more compact, shallow trench isolation (STI) has been developed and used in semiconductor memories. STI isolates adjacent diffusion layers via a shallow trench that can have a depth of about 0.3 μm.

FIG. 10 is a plan view of a conventional semiconductor memory having an STI structure. FIG. 11(A) is a cross sectional view of the conventional semiconductor memory of FIG. 10 taken along the line a-a. FIG. 11(B) is a cross sectional view of the conventional semiconductor memory of FIG. 10 taken along the line b-b. FIG. 11(C) is a cross sectional view of the conventional semiconductor memory of FIG. 10 taken along the line c-c.

The conventional semiconductor memory of FIG. 10 includes transistors (Q21 to Q24). Transistors (Q21 to Q24) are formed by N⁺ diffusion layers (L21 and L22) and gates (FG21 to FG24). Source lines SN are used to connected sources of transistors (Q21 to Q24). Bit lines (BL21T, BL21N, BL22T, and BL22N) are respectively connected to drains of transistors (Q21 to Q24). Bit lines (BL21T, BL21N, BL22T, and BL22N) are formed above the gates (FG21 to FG24).

Also included are through holes (H21 to H24 and H31 to H36). Through hole H21 connects bit line BL21N to gate FG21. Through hole H22 connects bit line BL21T to gate FG22. Through hole H23 connects bit line BL22T to gate FG23. Through hole H24 connects bit line BL22N to gate FG24. Through hole H31 connects bit line BL21T to N⁺ diffusion layer L21 at the drain of transistor Q21. Through hole H32 connects bit line BL21N to N⁺ diffusion layer L22 at the drain of transistor Q22. Through hole H33 connects bit line BL22N to N⁺ diffusion layer L21 at the drain of transistor Q23. Through hole H34 connects bit line BL22T to N⁺ diffusion layer L22 at the drain of transistor Q24. Through hole 135 connects source line SN to N⁺ diffusion layer L21 at the sources of transistors (Q21 and Q23), respectively. Through hole H36 connects source line SN to N⁺ diffusion layer L22 at the sources of transistors (Q22 and Q24), respectively.

In the conventional semiconductor memory illustrated in FIG. 10 and 11, an element isolation area S having an STI structure is formed on the surface of a silicon semiconductor substrate. To form the element isolation area S, a thermal oxide is formed on the surface of the silicon semiconductor substrate with a thermal oxidation method. A field nitride film is formed on the thermal oxide film by CVD (chemical vapor deposition). Opening are formed in the field nitride film and the thermal oxide film by lithography and dry etching and trenches are formed in the silicon semiconductor substrate. An insulating material, such as a silicon oxide film, is deposited on the entire surface including the trenches of the substrate to bury the insulating material in the trenches. Then, the insulating material on the field nitride film is removed with an etch back method or chemical mechanical polishing (CMP) method to flatten the surface. The field nitride film is then removed by wet etching to form the element isolation area S having an STI structure in which the trench is filled with the insulating material.

However, in the process of forming the element isolation area S, the “step of burying the insulating material in the trenches” has the drawback that the field nitride film can serve as a visor that can prevent the satisfactory formation of the buried insulating material at the edge portions of the field nitride film. Thus, a “divot” can be formed at the edge portions of the field nitride film due to the absence of the insulating material. This can be illustrated in FIG. 12. FIG. 12 is a cross-sectional diagram of the conventional semiconductor device after the step of burying the insulating material in the trenches.

In this way, the edge portion of the diffusion layer (L21 and L22) and the film quality of the insulating material near the edge portions of the diffusion layer can be deteriorated.

In the conventional semiconductor memory as illustrated in FIGS. 10 and 11, the divot is in contact with a channel portion (FIG. 11(C)) and the N⁺ diffusion layer (FIG. 11(B)). By having such a divot in the channel portion, the transistor portion formed over the divot can have a low threshold value. This leads to undesirable transistor characteristics in this region that can adversely affect the inherent characteristics of the transistor.

Referring now to FIG. 13, a graph of the current characteristics of in regions of a conventional transistor including a divot is set forth.

As can be seen in FIG. 13, the current characteristics of the conventional transistor in the portion of the channel away from the divot are illustrated by the solid line. However, the dashed lines illustrate current characteristics of the conventional transistor in the portion of the channel formed with a divot. The three dashed lines illustrate a range of current characteristics due to fluctuations in the formation of the divot. As noted, the threshold voltage of the portion of the channel formed with a divot is considerably lower than the portion of the channel away from the divot.

One method that is being considered to prevent the formation of the divot is a sidewall STI. However, this approach increases the number of production steps and thus, increases production time and costs.

In view of the above discussion, it would be desirable to provide a semiconductor device such as a semiconductor memory device and including an element isolation area having a shallow trench isolation structure while maintaining desired characteristics.

### SUMMARY OF THE INVENTION

According to the present embodiments, a semiconductor device may include an element isolation area having a shallow trench isolation (STI) structure. The semiconductor device may include transistors. Each transistor may include a gate that may be square, rectangular, or circular loops in their plan views. The gates may be formed to cover edge portions on the sides of diffusion layers at an interface with the STI structure. In this way, divots may not cause adverse affects on desired operating characteristics.

According to one aspect of the embodiments, a semiconductor device may include an element isolation area having a shallow trench isolation structure and a transistor. The transistor may include a gate having side portions formed over edge portions of a diffusion layer adjacent to the element isolation area.

According to another aspect of the embodiments, the gate may form a closed loop in a plan view and may expose a center portion of the diffusion layer while covering edge portions on both sides of the diffusion layer.

According to another aspect of the embodiments, the closed loop may be rectangular.

According to another aspect of the embodiments, the closed loop may be circular.

According to another aspect of the embodiments, the transistor may be an insulated gate field effect transistor (IGFET).

According to another aspect of the embodiments, a plurality of transistors may include gates having side portions formed over edge portions of a diffusion layer adjacent to the element isolation area.

According to another aspect of the embodiments, the plurality of transistors may be included in a sense amplifier latch. The semiconductor device may be a semiconductor memory device.

According to another aspect of the embodiments, a semiconductor device may include an element isolation area having a shallow trench isolation structure. The semiconductor device may also include a first insulated gate field effect transistor (IGFET) formed in a first active region. The first IGFET may include a first gate having a first closed loop having first gate side portions formed over an interface between the first active region and the element isolation area.

According to another aspect of the embodiments, the first IGFET may have a first gate width for determining current capacity. The first gate side portions may essentially not be included in the first gate width.

According to another aspect of the embodiments, the first closed loop may be rectangular.

According to another aspect of the embodiments, the first closed loop may be circular.

According to another aspect of the embodiments, the semiconductor device may be a semiconductor memory device including a first bit line having a first bit line portion and a second bit line portion. The first gate may provide an electrical connection between the first bit line portion and the second bit line portion of the first bit line.

According to another aspect of the embodiments, the semiconductor device may include a second IGFET formed in a second active region. The second IGFET may include a second gate having a second closed loop having second gate side portions formed over an interface between the second active region and the element isolation area. A second bit line may include a first bit line portion and a second bit line portion. The second gate may provide an electrical connection between the first and second bit line portions of the second bit line.

According to another aspect of the embodiments, the first and second bit lines may form a complementary twisted bit line pair.

According to another aspect of the embodiments, a semiconductor device may include an element isolation area having a shallow trench isolation structure and a first insulated gate field effect transistor (IGFET). The first IGFET may be formed in a first active region and may include a first gate having a first closed loop. The first closed loop may have first and second essentially opposing sides and third and fourth essentially opposing sides. The third and fourth essentially opposing sides may be formed over an interface between the first active region and the element isolation area.

According to another aspect of the embodiments, the first and second opposing sides may be separated by a first source/drain region and may be adjacent to a second source/drain region outside the first closed loop.

According to another aspect of the embodiments, the current drive of the first IGFET may be essentially proportional to the distance between the third and fourth sides.

According to another aspect of the embodiments, the semiconductor device may include a second IGFET formed in a second active region. The second IGFET may include a second closed loop. The second closed loop may have first and second essentially opposing sides and third and fourth essentially opposing sides. The third and fourth essentially opposing sides may be formed over an interface between the second active region and the element isolation area.

According to another aspect of the embodiments, the first and second IGFETs may be cross-coupled to form a latch circuit.

According to another aspect of the embodiments, the semiconductor device may be a dynamic random access memory (DRAM) including a sense amplifier. The sense amplifier may include the first and second IGFETs.

### BRIEF DESCRIPTION OF THE DRAWINGS

FIG. 1 is a plan view of a semiconductor memory according to a first embodiment.

FIG. 2(A) is a cross sectional view of the semiconductor memory portion of FIG. 1 taken along the line a-a.

FIG. 2(B) is a cross sectional view of the semiconductor memory portion of FIG. 1 taken along the line b-b.

FIG. 2(C) is a cross sectional view of the semiconductor memory portion of FIG. 1 taken along the line c-c.

FIG. 3 is a circuit diagram of a semiconductor memory portion according to an embodiment.

FIG. 4 is a plan view of an entire semiconductor memory that includes a semiconductor memory portion according to an embodiment.

FIG. 5 is a graph illustrating the current characteristics of a transistor formed using an embodiment.

FIG. 6 is a plan view of semiconductor memory portion having a reduced transistor size.

FIGS. 7(A) and 7(B) are plan views of transistors formed with circular type gates according to FIGS. 1 and 6.

FIG. 8 is a plan view of a semiconductor memory according to a second embodiment.

FIG. 9(A) is a cross sectional view of the semiconductor memory portion of FIG. 8 taken along the line a-a.

FIG. 9(B) is a cross sectional view of the semiconductor memory portion of FIG. 8 taken along the line b-b.

FIG. 9(C) is a cross sectional view of the semiconductor memory portion of FIG. 8 taken along the line c-c.

FIG. 10 is a plan view of a conventional semiconductor memory having an STI structure.

FIG. 11(A) is a cross sectional view of the conventional semiconductor memory of FIG. 10 taken along the line a-a.

FIG. 11(B) is a cross sectional view of the conventional semiconductor memory of FIG. 10 taken along the line b-b.

FIG. 11(C) is a cross sectional view of the conventional semiconductor memory of FIG. 10 taken along the line c-c.

FIG. 12 is a cross-sectional diagram of a conventional semiconductor device after the step of burying the insulating material in the trenches.

FIG. 13 is a graph of the current characteristics of in regions of a conventional transistor including a divot.

### DETAILED DESCRIPTION OF THE EMBODIMENTS

Various embodiments of the present invention will now be described in detail with reference to a number of drawings.

Embodiment 1:

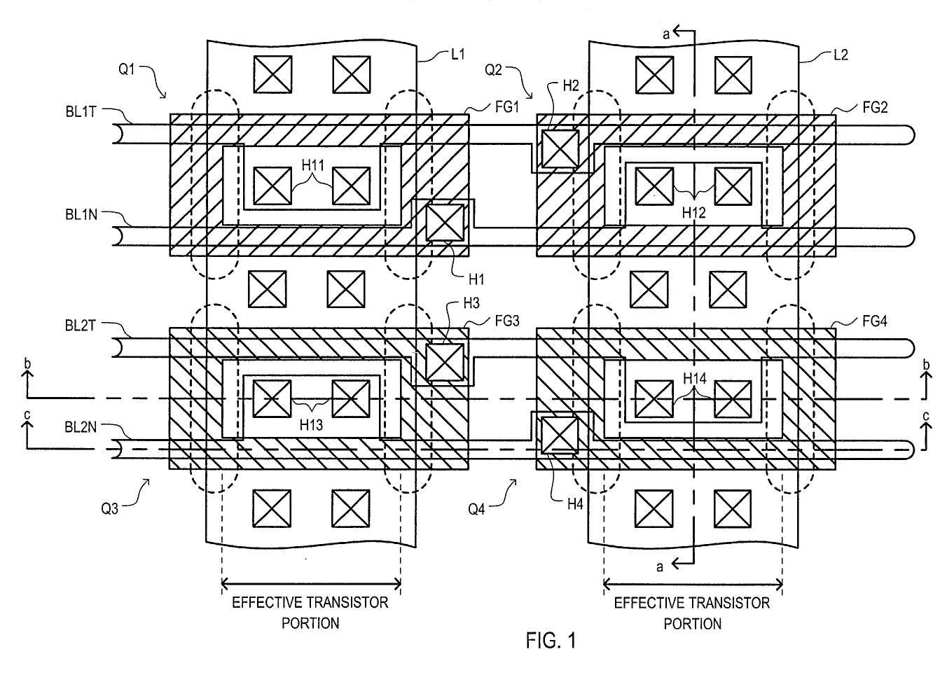

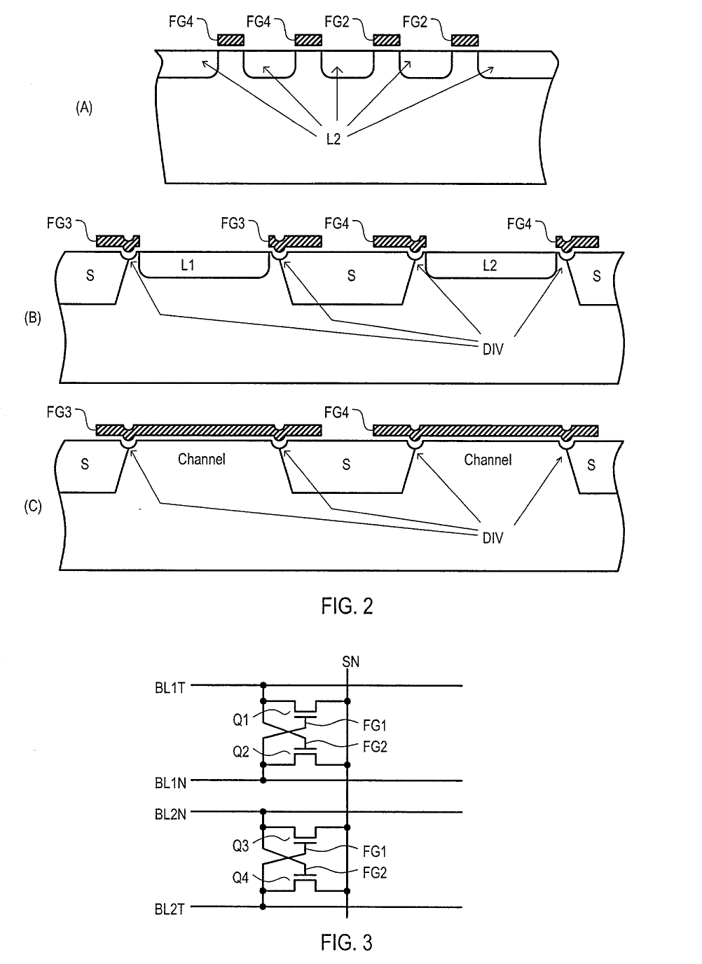

FIG. 1 is a plan view of a semiconductor memory according to a first embodiment. FIG. 2(A) is a cross sectional view of the semiconductor memory portion of FIG. 1 taken along the line a-a. FIG. 2(B) is a cross sectional view of the semiconductor memory portion of FIG. 1 taken along the line b-b. FIG. 2(C) is a cross sectional view of the semiconductor memory portion of FIG. 1 taken along the line c-c. FIG. 3 is a circuit diagram of the semiconductor memory portion illustrated in FIG. 1.

Referring now to FIGS. 1 to 3, the semiconductor memory portion may include transistors (Q1 to Q4). Transistors (Q1 to Q4) may be formed by N⁺ diffusion layers (L1 and L2) and gates (FGI to FG4). Source line SN may be connected sources of transistors (Q1 to Q4). Bit lines (BL1T, BL1N, BL2N, and BL2T) may be respectively connected to drains of transistors (Q1 to Q4). Bit lines (BL1T, BL1N, BL2T, and BL2N) may be formed above the gates (FG1 to FG4). It is noted that bit lines (BL1T, BLIN, BL2T, and BL2N) have been omitted in FIG. 2 to avoid unduly cluttering the figures.

Gates (FG1 to FG4) may be square, rectangular, or circular loop gates and may be formed with polysilicon over N⁺ diffusion layers (L1 and L2).

The circuit diagram semiconductor memory portion illustrated in FIGS. 1 to 3 may be portions of sense amplifier circuits.

Referring now to FIG. 3, a first sense amplifier circuit may include transistors (Q1 and Q2) in a cross coupled configuration. A second sense amplifier circuit may include transistors (Q3 and Q4) in a cross coupled configuration. Transistor Q1 may have a source connected to source line SN, a drain connected to bit line BL1T and a gate connected to bit line BL1N. Transistor Q2 may have a source connected to source line SN, a drain connected to bit line BL1N and a gate connected to bit line BL1T. Transistor Q3 may have a source connected to source line SN, a drain connected to bit line BL2N and a gate connected to bit line BL2T. Transistor Q4 may have a source connected to source line SN, a drain connected to bit line BL2T and a gate connected to bit line BL2N. Transistors (Q1 and Q2) may form a first latch. Transistors (Q3 and Q4) may form a second latch.

Bit lines (BL1T and BL1N) may form a first complementary bit line pair electrically connected to a first column of memory cells (not shown). Bit lines (BL2T and BL2N) may form a second complementary bit line pair electrically connected to a second column of memory cells (not shown).

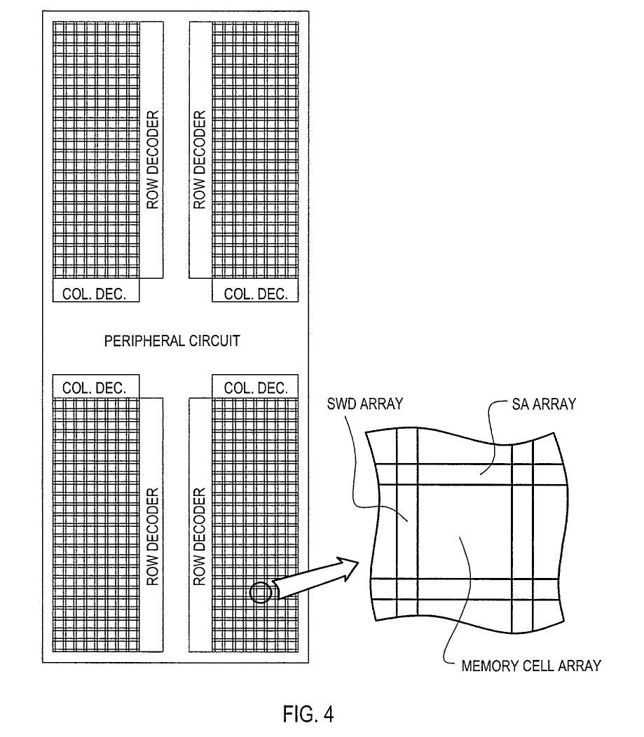

Referring now to FIG. 4, a plan view of the entire semiconductor memory that includes semiconductor memory portion illustrated in FIG. 1 is set forth.

The semiconductor memory portion illustrated in FIGS. 1 to 3, can be a portion of the semiconductor memory of FIG. 4. The semiconductor memory of FIG. 4 may include peripheral circuits, row decoders, column decoders, and groups of memory cell arrays. A memory cell array may be surrounded by a sense amplifier array (SA ARRAY) and a sub-word line driver array (SWD ARRAY). The semiconductor memory portion illustrated in FIGS. 1 to 3 may be included in the sense amplifier array (SA ARRAY) illustrated in FIG. 4.

Bit lines (BL1T, BL1N, BL2T, and BL2N) may be formed above the gates (FG1 to FG4).

Through holes (H1 to H4 and H11 to H14) may also be included and may provide an electrical connection between layers. Through hole H1 may connect bit line BL1N to gate FG1. Through hole H2 may connect bit line BL1T to gate FG2. Through hole H3 may connect bit line BL2T to gate FG3. Through hole H4 may connect bit line BL2N to gate FG4.

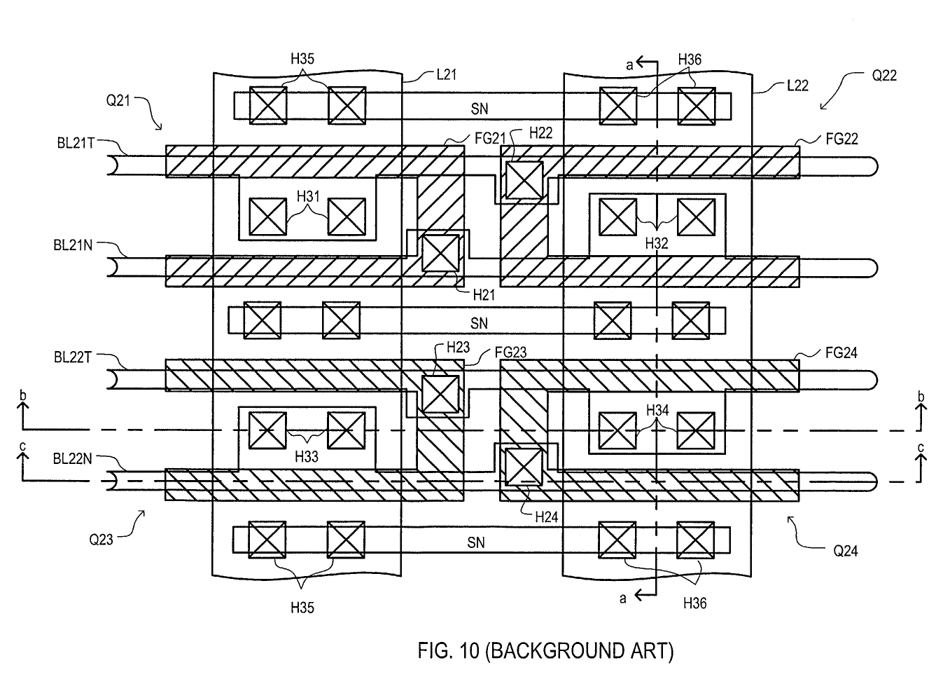

Through hole H11 may connect bit line BL1T to N⁺ diffusion layer L1 at the drain of transistor Q1. Through hole H12 may connect bit line BL1N to N⁺ diffusion layer L2 at the drain of transistor Q2. Through hole H13 may connect bit line BL2N to N⁺ diffusion layer L1 at the drain of transistor Q3. Through hole H14 may connect bit line BL2T to N⁺ diffusion layer L2 at the drain of transistor Q4. The source line and corresponding connections may be the essentially the same as in the conventional semiconductor memory device illustrated in FIG. 10, thus the description and structure may be omitted to avoid unduly cluttering FIG. 1.

In this way, transistors (Q1 to Q4) having a circuit configuration as illustrated in FIG. 3 may be formed.

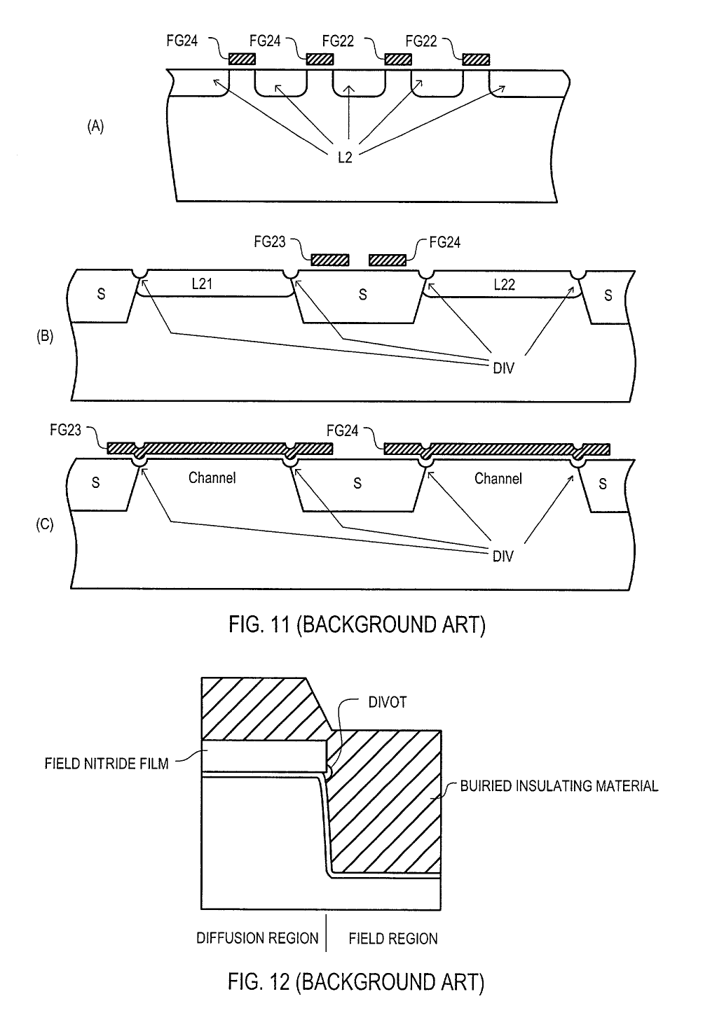

The method of forming the isolation area (STI structure) has been discussed in the background with reference to FIGS. 10 and 11.

In the embodiment as illustrated in FIGS. 1-3, gate FG1 may be a loop that can be formed to cover the right and left portions (the interface between the field and diffusion layer) of the diffusion layer Li and may protrude over both the diffusion layer Li and isolation area S. Similarly, gate FG2 may be formed to cover the right and left portions of the diffusion layer L2 and may protrude over both the diffusion layer and isolation area S. Gate FG3 may be formed to cover the right and left portions of the diffusion layer L1 and may protrude over both the diffusion layer and isolation area S. Gate FG4 may be formed to cover the right and left portions of the diffusion layer L2 and may protrude over both the diffusion layer and isolation area S.

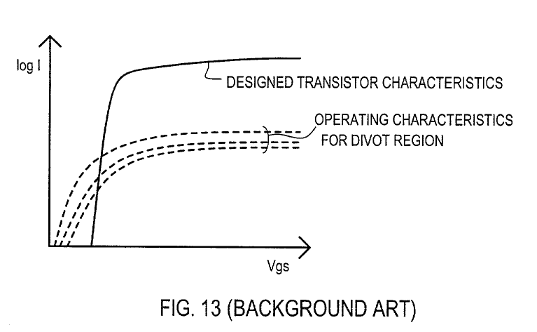

As described above, divots DIV may be formed in the STI structured element isolation areas S that may be present at the edges of diffusion layers (L1 and L2). In the conventional semiconductor device as illustrated in FIG. 11(B), diffusion layers (L21 and L22) may be in contact with the divots and may cause the respective transistors to have a low threshold value (Vt) formed in the divot region. Thus, undesired transistor characteristics may be obtained as illustrated in FIG. 13.

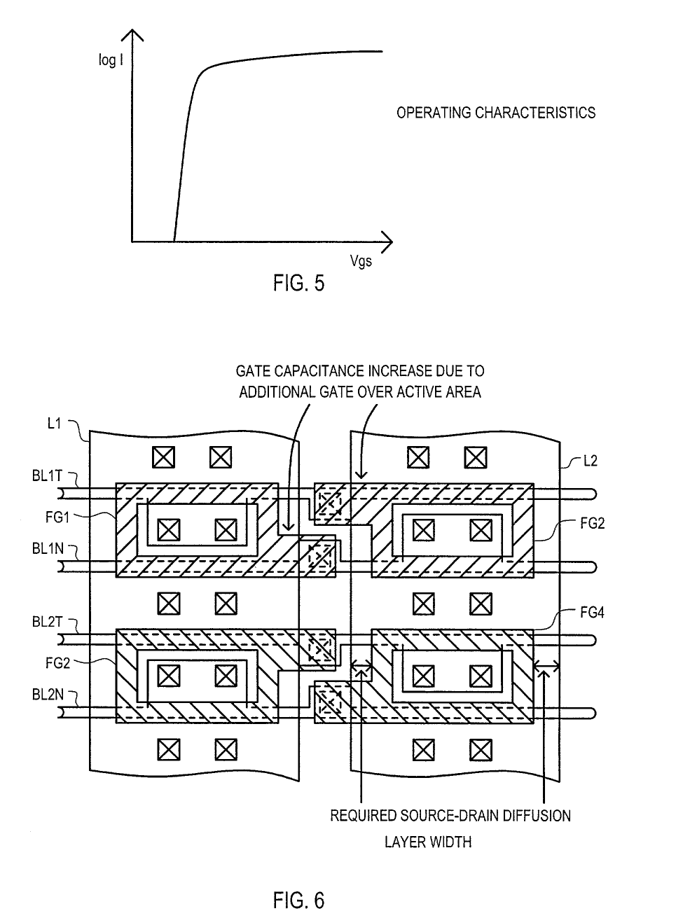

To address this problem, the embodiment illustrated in FIGS. 1 and 2, may include gates (FG1 to FG4) that are formed to cover the edge portions (the interface between the field and the diffusion layer) of the diffusion layers (L1 and L2). In this way, the divots DIV around the diffusion layers (Li and L2) may be covered with gates (FGi to FG4). This may prevent effective transistor areas from being formed in the edge portions of the diffusion layers (L1 and L2). The only effective transistor regions may be formed in the areas within the left and right sides of the formed gates (FG1 to FG4). This may prevent the characteristics of the divots DIV from exerting an undesired influence upon the characteristics of the transistors (FG1 to FG4). Desired transistor characteristics may be obtained as illustrated in FIG. 5.

Referring now to FIG. 5, a graph illustrating the current characteristics of a transistor formed using an embodiment is set forth. The graph of FIG. 5 illustrates the source drain current versus the gate to source voltage.

Because the gates (FG1 to FG4) may be formed in a loop configuration to surround the drain diffusion layers formed by diffusion layers (L1 and L2), the capacitance of each gate and the capacitance of each diffusion layer may be made constant even if the formation positions of the gates (FG1 to FG4) are shifted with respect to the diffusion layers (L1 and L2).

Also, because the divots DIV may be covered by the gates (FG1 to FG40, it may not be necessary to greatly modify the conventional production process. This, it may be possible to obtain desired transistor characteristics without increasing costs caused by the modification of the production process.

Referring now to FIG. 6, a plan view of a semiconductor memory portion. The layout of FIG. 6 illustrates a case where the gates (FG1 to FG4) may not be formed over the edge portions of the diffusion layers (L1 and L2) and the area of the transistors may be reduced.

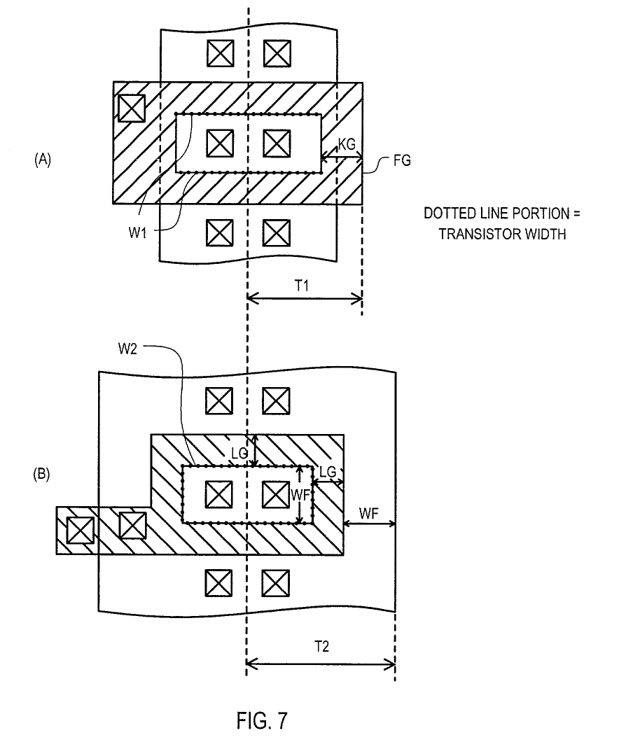

The effect of reducing the transistor area will now be described with reference to FIG. 7. FIGS. 7(A) and 7(B) are plan views of transistors formed with circular gates according to an embodiment.

As shown in FIG. 7(A), the effective size (gate width) of the transistor of the semiconductor memory (for example the embodiment illustrated in FIG. 1) may be represented by W1. W1 may be the twice distance between the inside edge of the side gate portions. T1 can represent one half the horizontal space consumed by the layout of the transistor of FIG. 7(A).

As shown in FIG. 7(B), the effective size (gate width) of the transistor of the semiconductor memory (for example the embodiment illustrated in FIG. 6) may be represented by W2. W2 may be the inside perimeter of the gate. T2 can represent one half the horizontal space consumed by the layout of the transistor of FIG. 7(B).

T1 and T2 can be represented by the following equations.

T1=W1/4+KG (1)

T2=W2/4−WF/2+LG+WF (2)

In the above equations, LG can be the gate length. KG can be the width of the portions of the gate overlapping the diffusion layers (L1 and L2) and the field (STI). WF may be ½ the width of the drain diffusion layer of the transistor illustrated in FIG. 7(B). When W=W1=W2, the following equation may be obtained from equations (1) and (2).

$$\begin{matrix}T 1 - T 2 = ( W / 4 + KG ) - ( W / 4 - WF / 2 + LG + WF ) \\ = KG - ( - WF / 2 + LG + WF ) \\ = KG - ( LG + WF / 2 )\end{matrix} \qquad ( 3 )$$

As seen from equation (3), because the width KG of gate portions overlapping the edge portions of the diffusion layers (L1 and L2) and the field (STI) may be smaller than the value obtained by adding up the gate length LG and WF/2, the area of the transistor illustrated in FIG. 7(A) may be smaller than the area of the transistor as illustrated in FIG. 7(B). Thus, the area of a semiconductor memory of the embodiment illustrated in FIG. 1 may be reduced as compared to the semiconductor memory illustrated in FIG. 6.

It is noted that although the size of the circular gate in FIG. 6 may be smaller than the size of the circular gate in the embodiment of FIG. 1, the required source drain diffusion layer width creates a space consumption in the horizontal direction for the transistor configuration of FIG. 6 that may not be necessary in the embodiment of FIG. 1. It is also noted that a semiconductor memory using transistors as illustrated in FIG. 6 may include a gate portion that is over the diffusion areas, which may not provide an appreciable current path from the source to the drain of the transistor. This gate portion may increase gate capacitance by providing an additional gate area over the active area. In this way, the gate capacitance of a transistor in the embodiment of FIG. 1 may not appreciably differ from a configuration having transistors configured as illustrated in FIG. 6.

In the embodiment illustrated in FIG. 1 (using a transistor as in FIG. 7(A)), width KG of gate portions overlapping the edge portions of the diffusion layers (L1 and L2) and the field (STI) may be approximately 0.3 μm. This may properly compensate for errors caused by a stepper, ion injection diffusion error, divot size and/or other production variations.

Embodiment 2:

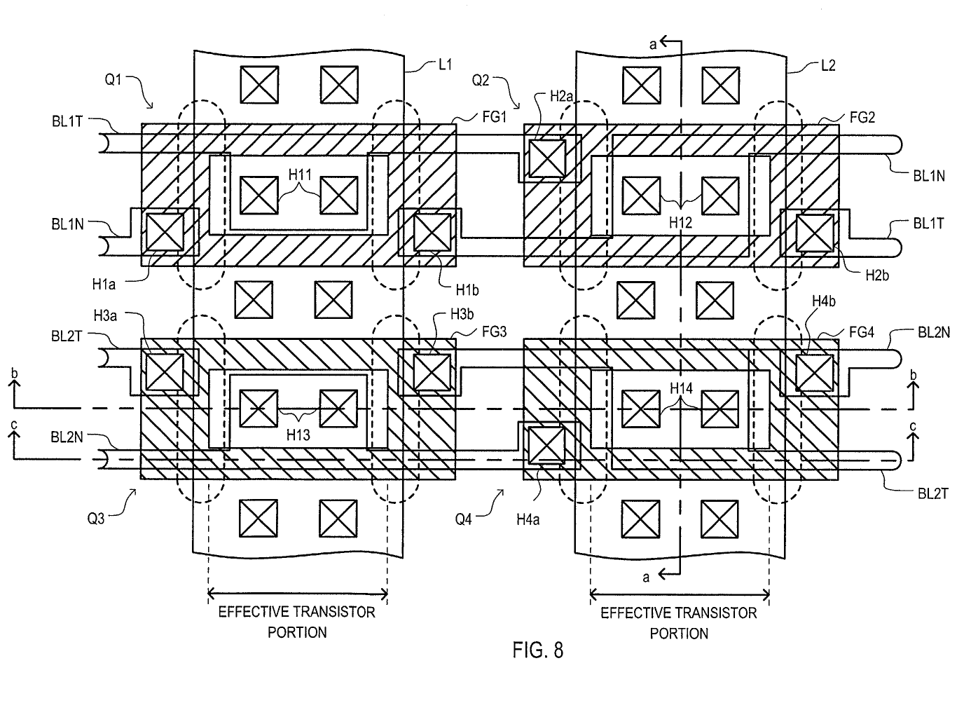

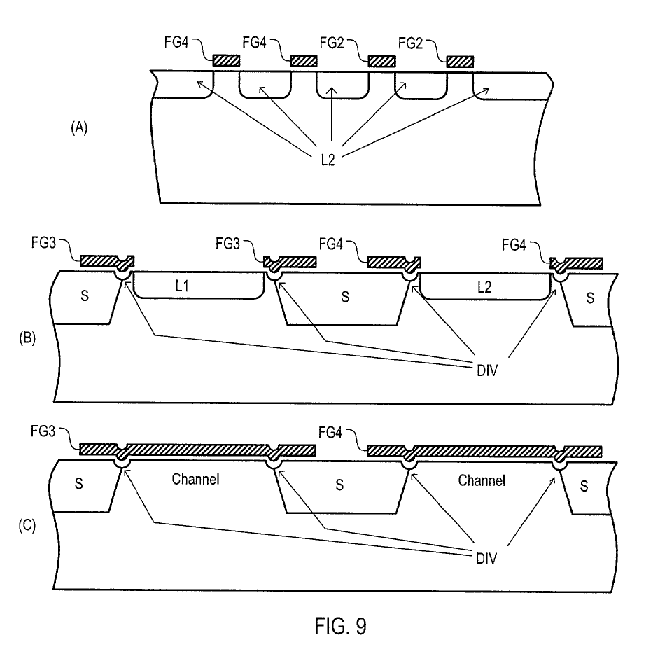

FIG. 8 is a plan view of a semiconductor memory according to a second embodiment. FIG. 9(A) is a cross sectional view of the semiconductor memory portion of FIG. 8 taken along the line a-a. FIG. 9(B) is a cross sectional view of the semiconductor memory portion of FIG. 8 taken along the line b-b. FIG. 9(C) is a cross sectional view of the semiconductor memory portion of FIG. 8 taken along the line c-c. FIG. 3 is also a circuit diagram of the semiconductor memory portion illustrated in FIG. 8.

The second embodiment illustrated in FIG. 8 may include similar constituents as the first embodiment illustrated in FIG. 1. Such constituents may be referred to by the same general reference character.

Referring now to FIGS. 8 and 9, the semiconductor memory portion may include transistors (Q1 to Q4). Transistors (Q1 to Q4) may be formed by N⁺ diffusion layers (L1 and L2) and gates (FG1 to FG4). Source line SN may be connected sources of transistors (Q1 to Q4). Bit lines (BL1T, BL1N, BL2N, and BL2T) may be respectively connected to drains of transistors (Q1 to Q4). Bit lines (BL1T, BL1N, BL2T, and BL2N) may be formed above the gates (FG1 to FG4). It is noted that bit lines (BL1T, BL1N, BL2T, and BL2N) have been omitted in FIG. 9 to avoid unduly cluttering the figures.

Gates (FG1 to FG4) may be square, rectangular, or circular loop gates and may be formed with polysilicon over N⁺ diffusion layers (L1 and L2).

In the embodiment as illustrated in FIGS. 8 and 9, gate FG1 may be a loop that can be formed to cover the right and left portions (the interface between the field and diffusion layer) of the diffusion layer L1 and may protrude over both the diffusion layer L1 and isolation area S. Similarly, gate FG2 may be formed to cover the right and left portions of the diffusion layer L2 and may protrude over both the diffusion layer and isolation area S. Gate FG3 may be formed to cover the right and left portions of the diffusion layer L1 and may protrude over both the diffusion layer and isolation area S. Gate FG4 may be formed to cover the right and left portions of the diffusion layer L2 and may protrude over both the diffusion layer and isolation area S.

The circuit diagram semiconductor memory portion illustrated in FIGS. 8, 9, and 3 may be portions of sense amplifier circuits.

Bit lines (BL1T, BLIN, BL2T, and BL2N) may be formed above the gates (FG1 to FG4).

Through holes (H1a-H1b to H4a-H4b and H11 to H14) may also be included and may provide an electrical connection between layers. Through hole H1a may connect a right portion of bit line BL1N to gate FG1 and through hole Hlb may connect a left portion of bit line BL1N to gate FG1. Through hole H2a may connect a left portion of bit line BL1T to gate FG2 and through hole H2b may connect a right portion of bit line BL1T to gate FG2. Through hole H3a may connect a left portion of bit line BL2T to gate FG3 and through hole H3b may connect a right portion of bit line BL2T to gate FG3. Through hole H4a may connect a left portion of bit line BL2N to gate FG4 and through hole H4b may connect a right portion of bit line BL2N to gate FG4.

Through hole H11 may connect bit line BL1T to N⁺ diffusion layer L1 at the drain of transistor Q1. Through hole H12 may connect bit line BL1N to N⁺ diffusion layer L2 at the drain of transistor Q2. Through hole H13 may connect bit line BL2N to N⁺ diffusion layer L1 at the drain of transistor Q3. Through hole H14 may connect bit line BL2T to N⁺ diffusion layer L2 at the drain of transistor Q4. The source line and corresponding connections may be the essentially the same as in the conventional semiconductor memory device illustrated in FIG. 10, thus the description and structure may be omitted to avoid unduly cluttering FIG. 8.

In this way, transistors (Q1 to Q4) having a circuit configuration as illustrated in FIG. 3 maybe formed.

The effect of embodiment 2 illustrated in FIGS. 8 and 9 may be essentially the same as Embodiment 1. However, in embodiment 2, the bit lines may include left and right bit line portions that may be electrically connected through the respective gate (FG1 to FG4). In this way, bit lines may be formed in crossed or twisted complementary pairs. That is, bit lines (BL1T and BL1N) may be twisted with respect to each other so that they may form a complementary crossed or twisted pair. Likewise, bit lines (BL2T and BL2N) may be twisted with respect to each other so that they may form a complementary crossed or twisted pair. Left and right bit line portions may be electrically connected through a respective gate (FG1 to FG4).

In accordance with the present embodiments, the gates may be formed over the edge portions of the diffusion layer and element isolation area so that divots present around this interface may be covered by the gates. In this way, areas that are disposed between such divots may be used as effective semiconductor devices without using the areas including the divots. Thus, divots may be prevented from adversely affecting the operating characteristics of the semiconductor device so that desired operating characteristics may be obtained. Such characteristics may include voltage current characteristics of a semiconductor devices such as a transistor. The transistor may be a insulated gate field effect transistor (IGFET), as just one example.

Because the divots may be covered by the gate patterns, it may be unnecessary to greatly modify the conventional production process. Thus, it may be possible to obtain desired electrical properties without increasing costs due to modifying or complicating the production process. Also, layout area and overall chip size may be reduced as compared to a device that is formed where the gates do not cover the edge portions of the diffusion layer, but are contained in a circular or similar fashion within the diffusion layer.

The gates may be square, rectangular, or circular loops in their plan views and may be formed to expose center portions of the diffusion layers surrounded by the element isolation area while covering the edge portions on both sides of the diffusion layers. Thus, the capacitance of each gate and the capacitance of each diffusion layer may be made constant even if the formation of the gates are shifted with respect to the diffusion layers.

It is understood that the embodiments described above are exemplary and the present invention should not be limited to those embodiments. Specific structures should not be limited to the described embodiments.

Thus, while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device, comprising:
an element isolation area having a shallow trench isolation structure; and
a transistor including a gate having side portions formed over edge portions of a diffusion layer adjacent to the element isolation area.

2. The semiconductor device according to claim 1, wherein:
the gate forms a closed loop in a plan view and exposes a center portion of the diffusion layer while covering edge portions on both sides of the diffusion layer.

3. The semiconductor device according to claim 2, wherein:
the closed loop is rectangular.

4. The semiconductor device according to claim 2, wherein:
the closed loop is circular.

5. The semiconductor device according to claim 1, wherein:
the transistor is an insulated gate field effect transistor.

6. The semiconductor device according to claim 1, further including:
a plurality of transistors including gates having side portions formed over edge portions of a diffusion layer adjacent to the element isolation area.

7. The semiconductor device according to claim 6, wherein:
the plurality of transistors are included in a sense amplifier latch; and
the semiconductor device is a semiconductor memory device.

8. A semiconductor device, comprising:
an element isolation area having a shallow trench isolation structure; and
a first insulated gate field effect transistor (IGFET) formed in a first active region, the first IGFET including a first gate having a first closed loop with first gate side portions formed over an interface between the first active region and the element isolation area.

9. The semiconductor device according to claim 8, wherein:
the first IGFET has a first effective gate width for determining current capacity; and
the first gate side portions of the first gate are essentially not included in the first effective gate width.

10. The semiconductor device according to claim 8, wherein:
the first closed loop is rectangular.

11. The semiconductor device according to claim 8, wherein:
the first closed loop is circular.

12. The semiconductor device according to claim 8, wherein the semiconductor device is a semiconductor memory, further including:
a first bit line having a first first bit line portion and a second first bit line portion; and
the first gate provides an electrical connection between the first first bit line portion and the second first bit line portion.

13. The semiconductor device according to claim 12, further including:
a second IGFET formed in a second active region, the second IGFET including a second gate having a second closed loop with second gate side portions formed over an interface between the second active region and the element isolation area;
a second bit line having a first second bit line portion and a second second bit line portion; and
the second gate provides an electrical connection between the first second bit line portion and the second second bit line portion.

14. The semiconductor device according to claim 13, wherein:
the first and second bit lines form a complementary twisted bit line pair.

15. A semiconductor device, comprising:
an element isolation area having a shallow trench isolation structure; and
a first insulated gate field effect transistor (IGFET) formed in a first active region, the first IGFET including a first gate having a first closed loop with first and second essentially opposing sides and third and fourth essentially opposing sides wherein the third and fourth essentially opposing sides are formed over an interface between the first active region and the element isolation area.

16. The semiconductor device according to claim 15, wherein:
the first and second opposing sides are separated by a first source/drain region and are adjacent to a second source/drain region outside the first closed loop.

17. The semiconductor device according to claim 15, wherein:
the current dr ive of the first IGFET is essentially proportional to the distance between the third and fourth sides.

18. The semiconductor device according to claim 15, further including:
a second insulated gate field effect transistor (IGFET) formed in a second active region, the second IGFET including a second gate having a first closed loop with first and second essentially opposing sides and third and fourth essentially opposing sides wherein the third and fourth essentially opposing sides are formed over an interface between the second active region and the element isolation area.

19. The semiconductor device according to claim 18, wherein:
the first and second IGFETs are cross-coupled to form a latch circuit.

20. The semiconductor device according to claim 18, wherein:
the semiconductor device is a dynamic random access memory including a sense amplifier; and
the sense amplifier includes the first and second IGFETs.
